(19) United States
(12) Patent Application Publication
(10) Pub. No.: US 2011/0168650 A1
(43) Pub. Date: Jul. 14, 2011

(54) Communication rack

(76) Inventor: Yu-Ho Liang, Bangiao City (TW)

(21) Appl. No.: 12/656,795

(22) Filed: Feb. 17, 2010

(30) Foreign Application Priority Data
Jan. 13, 2010 (TW) 099200642

(51) Int. Cl. H05K 7/18; A47B 96/06

(52) U.S. Cl. 211/26

(57) ABSTRACT

A communication rack includes a stand, at least one support plate, a board, and a plurality of retainers. The stand forms at least two insertion slot rows and a plurality of positioning sections arranged between the insertion slot rows. Each insertion slot row comprises at least one insertion slot. The support plate is movably inserted in the insertion slot of the stand. The board is positioned on and supported by the support plate and the board includes a plurality of retention sections. Each retainers includes at least one counterpart positioning section and at least one pawl. The counterpart positioning section corresponds to the positioning section so as to be fixed together. The pawl corresponds to and engages with the retention sections to be fixed together.

### FIELD OF THE INVENTION

The present invention relates to a communication rack, and in particular to a communication rack comprising a stand that is made in a detachably assembled combination of components for detachment of the components to adjust a vertical dimension thereof.

### BACKGROUND OF THE INVENTION

Communication between modern electronic devices is frequent and fast. For example, a computer may carry out electrical transmission to other computers through a network cable. However, there are usually a great number of communication cables/wires, which is often disposed in a disordered manner, provided for connecting between various electronic devices. To handle such a problem of disorderly arranged large number of communication cables/wires (such as network cables), a communication rack is provided to receive the communication cables/wires to plug therein for communication connection.

Referring to FIGS. 1 and 2 of the attached drawings, a conventional communication rack is shown. The conventional communication rack comprises a board 1 and a one-piece stand 2. The board 1 forms a plurality of insertion holes 11, pairs of retention sections 12, and two frames 13 on an undersurface of the board. The stand 2 comprises a base 21, three pairs of support plates 22 extending from lateral sides of the stand, and two pairs of spring arms 23 also extending from the sides of the stand. Each spring arm 23 has a free end forming a pawl 231 corresponding to each of the retention sections 12. Two diagonal corners of the stand 2 form mounting sections 211, each of which defines a mounting slot 2111.

The undersurface of the board 1 is positioned on and supported on the support plates 22. The support plates 22 are arranged to have inside surfaces thereof in close proximity of outside surfaces of the two frames 13 so as to allow the pawls 231 of the spring arms 23 to engage retention sections 12 for positioning and fastening to form the communication rack. The conventional communication rack is mounted to a wall by first fitting the mounting slot 2111 of one mounting section 211 thereof to a projection (not shown) formed on the wall, followed by rotating the communication rack about the projection to have the mounting slot 2111 of another mounting section 211 fit to another projection (not shown) formed on the wall. The insertion holes 11 formed in the board 1 each receive therein a socket that is not shown therein and communication cables/wires connected to the sockets are received and retained between the board 1 and the stand 2.

Although the conventional communication rack provides a feature that allows for collective plugging, yet the stand 2 of the conventional communication rack is of a one-piece structure, which makes it non-adjustable in height thereof for accommodating an excessive amount of cables/wires and an additional or replacement stand must be provided to meet the need of accommodating the excessive amount of cables/wires. In this way, the original stand 2 is of no further use and must be disposed of. This causes a waste.

Thus, it is desired to provide a communication rack comprising a board and a stand between which a height is adjustable for accommodating various amount of communication cables/wires.

### SUMMARY OF THE INVENTION

An objective of the present invention is to provide a communication rack comprising a board and a stand between a height or vertical distance is adjustable freely by a user, whereby the communication rack can be used in both a normal condition where a predetermined amount of communication cables/wires is received in the vertical distance and an extraordinary condition where an excessive amount of communication cables/wires is received in the vertical distance, so that it is not necessary to replace and dispose of the stand and consequently, no waste may occur.

To realize the objective, the present invention provides a communication rack comprising a stand, at least one support plate, a board, and a plurality of retainers. The stand forms at least two insertion slot rows and a plurality of positioning sections arranged between the insertion slot rows. Each insertion slot row comprises at least one insertion slot. The at least one support plate is movably inserted in the insertion slot of the stand. The board comprises a plurality of retention sections. The board is positioned on and supported by the at least one support plate. Each retainers comprises at least one counterpart positioning section and at least one pawl. The counterpart positioning section corresponds to the positioning section so as to be fixed together. The pawl corresponds to and engages with the retention sections to be fixed together.

As such, a user may freely adjust the height between the board and the stand so that the communication rack can be used in a normal condition or a condition of excessive amount of cables/wires. There will no need to replace and dispose of the stand. Consequently, no waste may occur.

Preferably, in the communication rack according to the present invention, the two insertion slot rows respectively comprise a plurality of insertion slots and the at least one support plate comprises a plurality of support plates corresponding to the insertion slots. Each of the support plates is movably inserted in each of the insertion slots.

Further, each of the insertion slots comprises a long shallow recess and a short deep recess that is made deeper than the shallow recess. Each support plate has two long edges and two short edges. The long shallow recess is sized to receive movable insertion of one of the long edges of the support plate therein. The short deep recess is sized to receive movable insertion of one of the short edges of the support plate therein.

Further, the retainer can be made in two types. The first type of retainer comprises two separate spring arms, each of which has an end forming a pawl and an opposite end forming a counterpart positioning section. The second type comprises two spring arms connected to each other. Each of the spring arms has an end forming a pawl and an opposite end connected to each other by the counterpart positioning section.

### BRIEF DESCRIPTION OF THE DRAWINGS

The present invention will be apparent to those skilled in the art by reading the following description of preferred embodiments thereof with reference to the drawings, in which:

FIG. 1 is an exploded view of a conventional communication rack;

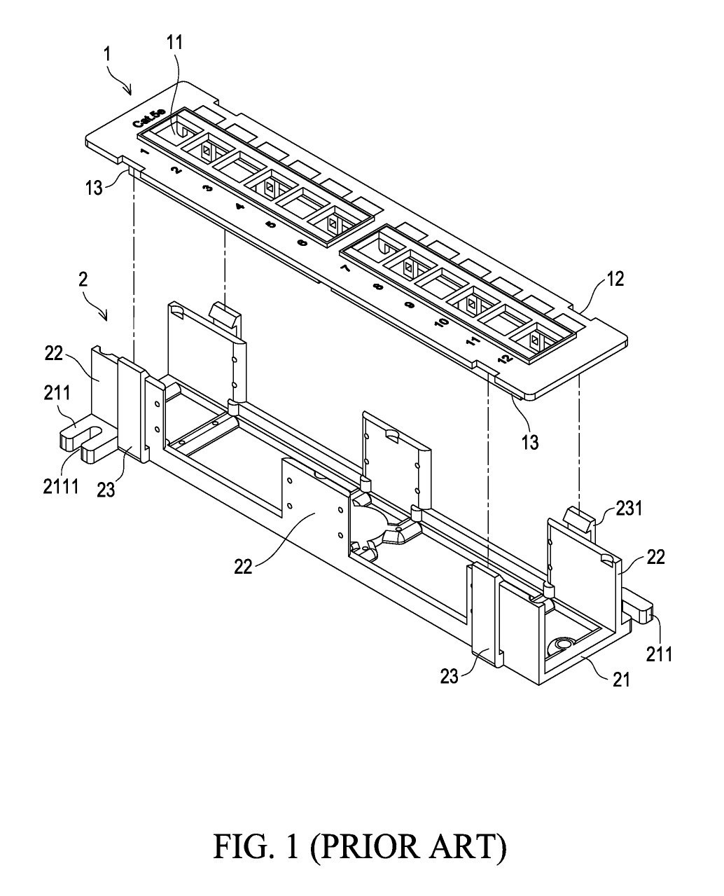

FIG. 2 is a perspective view of the conventional communication rack in an assembled form;

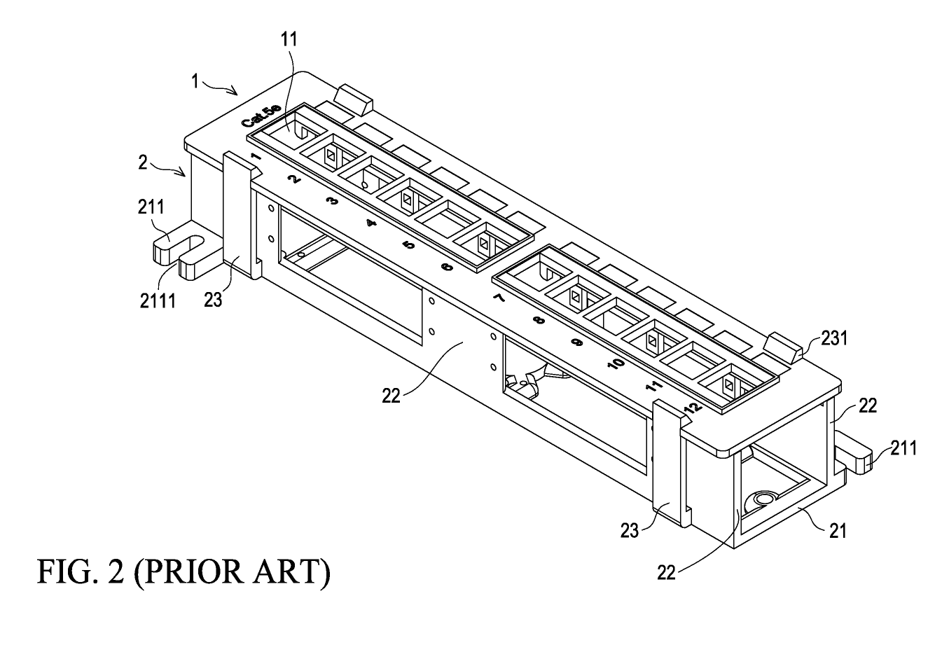

FIG. 3 is an exploded view of a communication rack constructed in accordance with a first embodiment of the present invention;

FIG. 4 is an assembled view of the present invention of FIG. 3;

FIG. 5 is a cross-sectional view of the present invention of FIG. 3;

FIG. 6 is another perspective view of the communication rack of the first embodiment of the present invention taken from the bottom side;

FIG. 7 is another perspective view of the communication rack of the first embodiment of the present invention in an assembled form;

FIG. 8 is an exploded view of a communication rack constructed in accordance with a second embodiment of the present invention;

FIG. 9 is a side elevational view of a communication rack constructed in accordance with a third embodiment of the present invention;

FIG. 10 is a side elevational view of a communication rack constructed in accordance with a fourth embodiment of the present invention; and

FIG. 11 is an exploded view of a communication rack constructed in accordance with a fifth embodiment of the present invention.

### DETAILED DESCRIPTION OF THE PREFERRED EMBODIMENTS

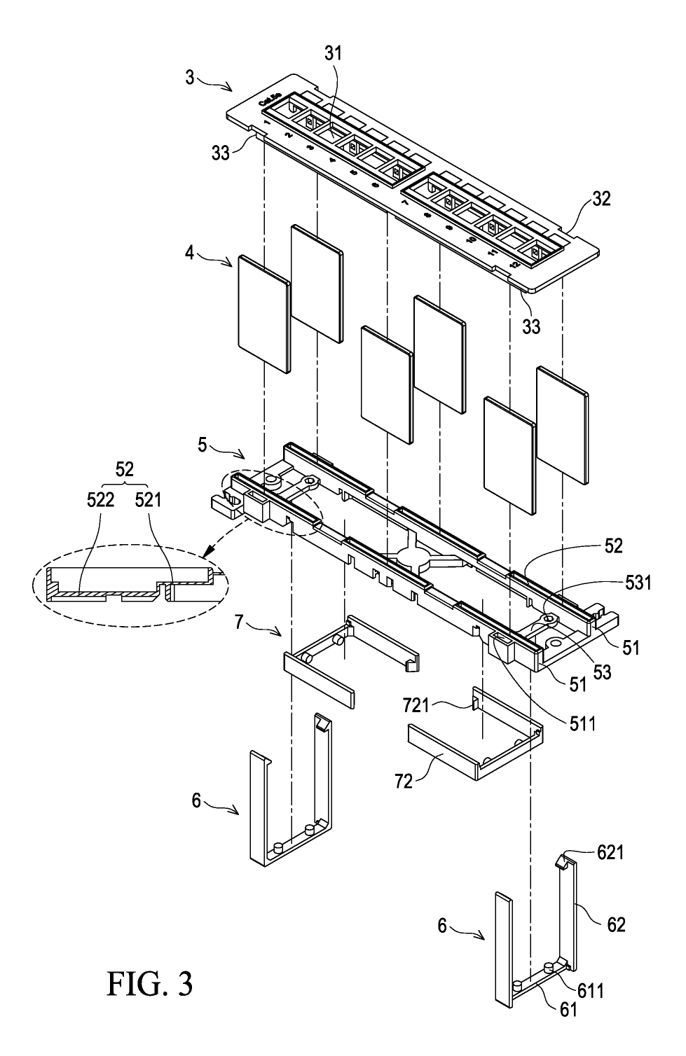

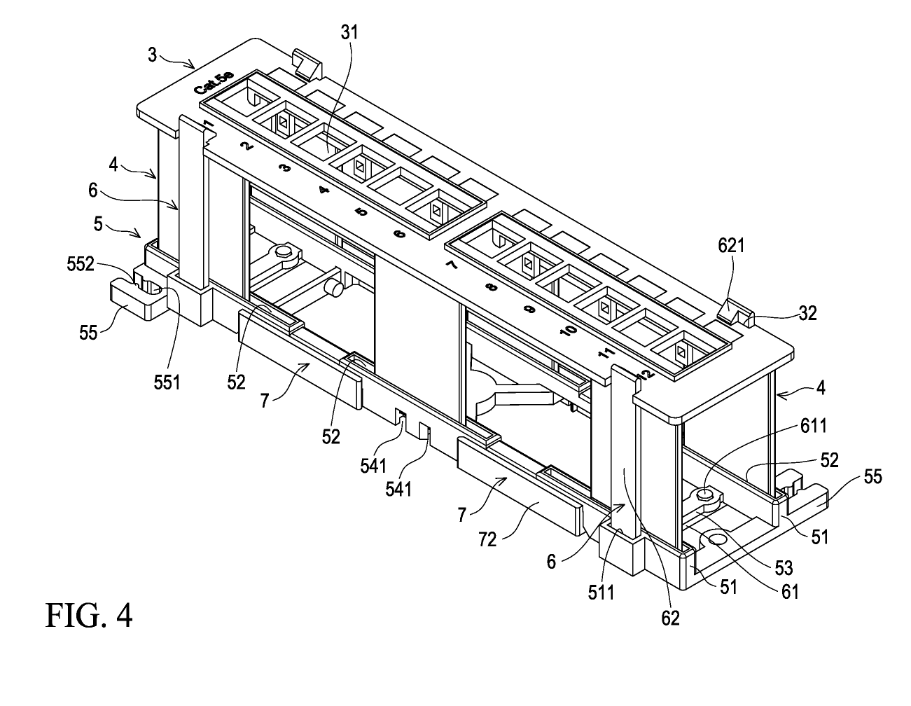

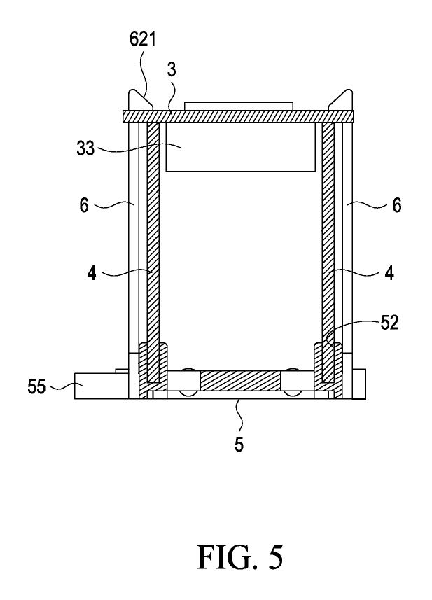

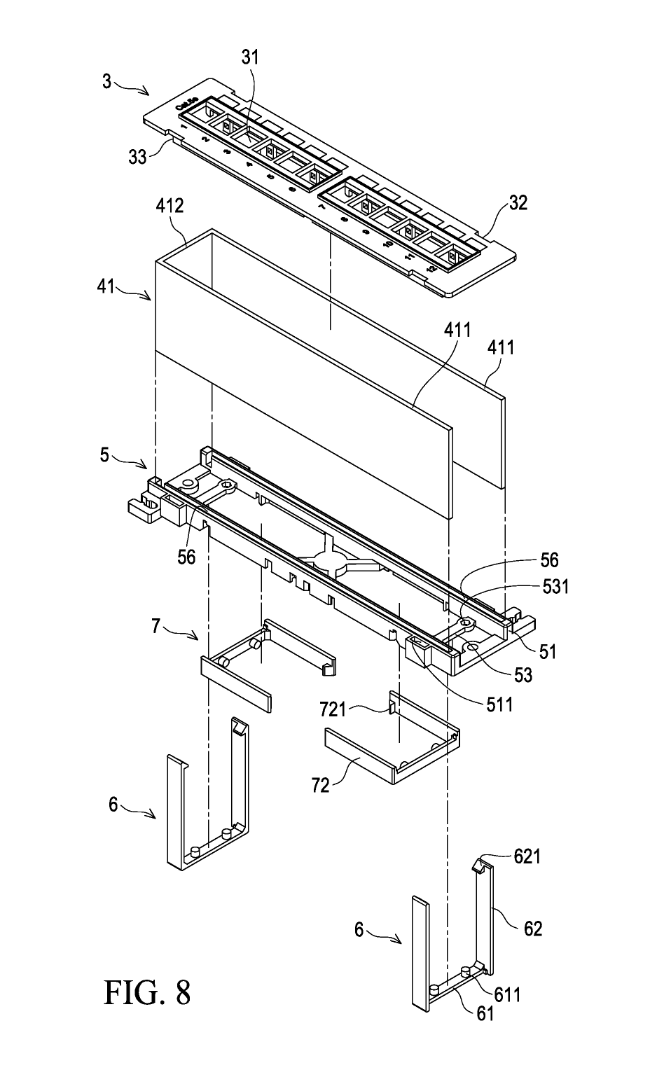

The present invention provides a communication rack of which a first embodiment according to the present invention is illustrated in FIGS. 3-7 and second, third, fourth, and fifth embodiments are respectively illustrated in FIGS. 8, 9, 10, and 11.

### First Embodiment

Referring to FIGS. 3-7, which show a communication rack constructed in accordance with a first embodiment of the present invention, the communication rack comprises a board 3, a plurality of support plates 4, a stand 5, and a plurality of retainers (comprised and illustrated by first retainer 6 and second retainer 7).

The stand 5 forms a plurality of insertion slot rows (not labeled), two side beams 51, and a plurality of positioning sections 53 arranged between the two side beams 51. In the embodiment illustrated, the number of the insertion slot rows and the number of the positioning sections 53 are both two, and the two insertion slot rows are respectively formed in the two side beams 51. Each of the insertion slot rows comprises a plurality of insertion slots 52. (In the embodiment illustrated, each insertion slot row comprises three insertion slots defined in the respective side beam.)

The support plates 4 are provided in the same number as the insertion slots 52. As shown in the drawings, each support plate 4 assumes a rectangular shape having two opposite long edges and two opposite short edges. The support plates 4 are respectively and movably inserted in the insertion slots 52 of the stand 5. In the embodiment illustrated in FIGS. 3-6, the support plates 4 are inserted into the insertion slots 52 with the short edges thereof and use the long edges to support the board 3 at a desired elevated height, whereby the distance between the board 3 and the stand 5 can be set to a maximum level for accommodating an excessive amount of communication cables/wires.

The board 3 comprises multiple pairs of retention sections 32. The board 3 has an undersurface on which two frames 33 are formed. The undersurface of the board 3 is positioned on and supported by the support plates 4. Under this condition, inside surfaces of the support plates 4 are in close proximity of outside surfaces of the frames 33.

The retainers comprise a plurality of first retainer 6 each having spring arms 62 and a plurality of second retainer 7 each having spring arms 72. The spring arms 62 of the first retainer 6 have a length (referred to as “first length” hereinafter) greater than a length (referred to as “second length” hereinafter) of the spring arms 72 of the second retainer 7, wherein normally, the second retainer 7 that have short spring arms 72 are used, but in case of an excessive amount of communication cables/wires, the first retainer 6 that have long spring arms 62 are used. The first retainer 6 and second retainer 7 are of the same construction, but with the lengths of the spring arms 62, 72 thereof being different. The following description is made for the first retainer 6, and vice versa, the second retainer 7 is also applicable. The first retainer 6 comprises two spring arms 62, a counterpart positioning section 61 that is formed between ends of the spring arms 62 and corresponding to one of the positioning sections 53, and two pawls 621 that are respectively formed on opposite ends of the spring arms 62. The pawls 621 of the first retainer 6 correspond to each pair of retention sections 32 of the board 3 and are able to engage with and thus fixed to each other with the counterpart positioning section 61 of the first retainer 6 being positioned on each positioning section 53 of the stand 5 to be fixed together.

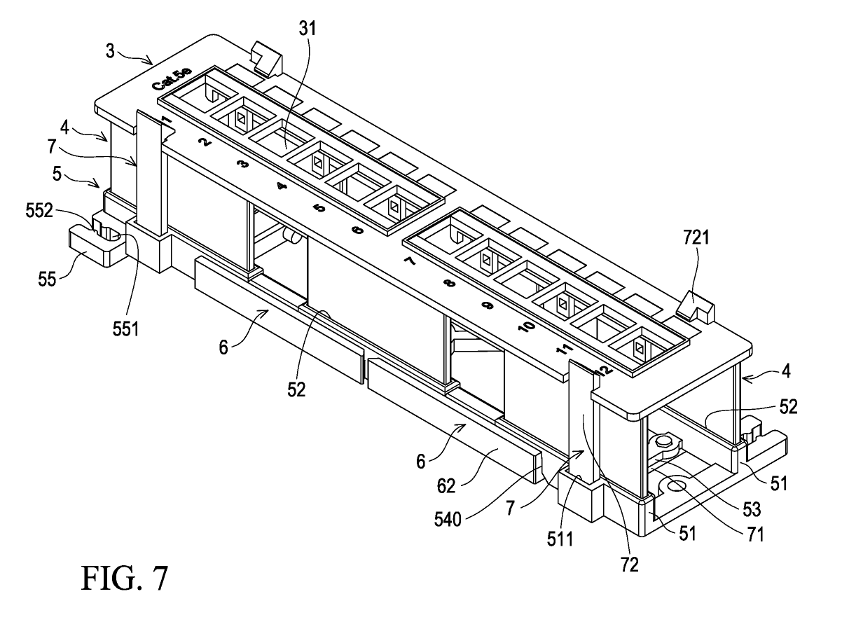

As shown in FIG. 3, each insertion slot 52 is composed of a long shallow recess 521 and a short deep recess 522 that is made deeper than the shallow recess 521. The long shallow recess 521 functions to receive a long edge of the support plate 4 to movably insert therein (as shown in FIG. 7), while the short deep recess 522 functions to receive a short edge of the support plate 4 to movably insert therein (as shown in FIGS. 3-6).

The board 3 may comprise a flat board (not shown), or alternatively a hole-forming board forming a plurality of insertion holes 31 (for receiving telecommunication plug of networking cable/wire) as shown in the drawings, or alternatively a terminal supporting board that carries a plurality of conductive terminals (not shown).

Each of the positioning sections 53 of the stand 5 forms a plurality of holes 531, and the counterpart positioning section 61 of each retainers (the first retainer 6 and the second retainer 7; illustrated by the first retainer 6) forms a plurality of pegs 611 corresponding to the holes, whereby the pegs 611 are insert into the holes 531 for positioning.

Peripheral sides of the stand 5 further form pairs of reinforcement holes 511, whereby the spring arms 62 of the first retainer (retainers includes the first retainer 6 and the second retainer 7; illustrated by the first retainer 6) are allowed to extend through the respective pairs of reinforcement holes 511 with interference being induced between the spring arms 62 and the reinforcement holes 511 to realize tight engagement.

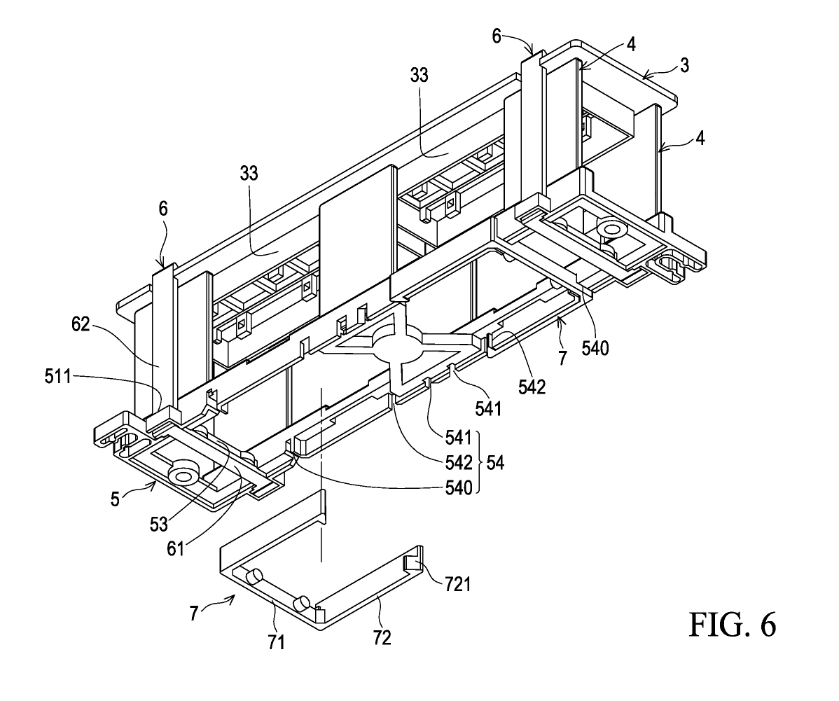

The stand 5 has a bottom forming a plurality of storage members 54 (as shown in FIG. 6). Each storage member 54 includes base receiving channels 540 for receiving and positioning the counterpart positioning sections 61 of the first retainer 6, first receiving channels 541 for receiving and positioning the pawls 621 of the first retainer 6, and second receiving channels 542 for receiving and positioning pawls 721 of the second retainer 7 (as shown in FIGS. 3 and 6). As shown in FIGS. 3 and 6, the spring arms 72 of the second retainer 7 also form pawls 721; and as shown in FIGS. 6 and 7, the spring arms 72 of the second retainer 7 are connected at ends thereof by a counterpart positioning section 71.

As shown in FIG. 3-6, when the first retainer 6 are used to retain between the board 3 and the stand 5, the storage members 54 can be used to receive and store the second retainer 7 that are not in use on the bottom of the stand 5; and similarly, when the second retainer 7 are used to retain between the board 3 and the stand 5 (as shown in FIG. 7), the storage members 54 can be used to receive and store the first retainer 6 that are not in use on the bottom of the stand 5 (not demonstrated in the drawings).

The stand 5 also forms a plurality of mounting sections 55 on the peripheral sides thereof. As shown in the drawings, the mounting sections are provided on two diagonally opposite corners of the stand 5. Each of the mounting sections 55 forms a mounting slot 551, and the mounting slot 551 has opposing side walls that form two protrusions 552 that is opposing but spaced from each other by a spacing distance. The spacing distance between the protrusions is slightly less than a diameter of a projection formed on for example a wall (not shown but being described in the section of “BACKGROUND OF THE INVENTION”), whereby when the communication rack is set between two projections provided on the wall, the two protrusions 552 can be set in retained engagement with an associated projection to realize sound and secure mounting of the rack on the wall.

### Second Embodiment

Referring to FIG. 8, a communication rack constructed in accordance with a second embodiment of the present invention is shown, the communication rack of the second embodiment is similar to that of the first embodiment, but comprises a support plate 41 and insertion slot rows are made in different forms.

As shown, the communication rack of the second embodiment comprises two insertion slot rows each comprising an elongate insertion slot 56 defined in the stand 5, and the support plate 41 comprises two side plate sections 411 and a connection section 412 connecting between ends of the two side plate sections 411. The two side plate sections 411 are respectively and movably insert into the two elongate insertion slots 56 with the connection section 412 spanning between the two insertion slots 56. Thus, by selecting a support plate 41 of different height, the height of the communication rack can be changed.

### Third Embodiment

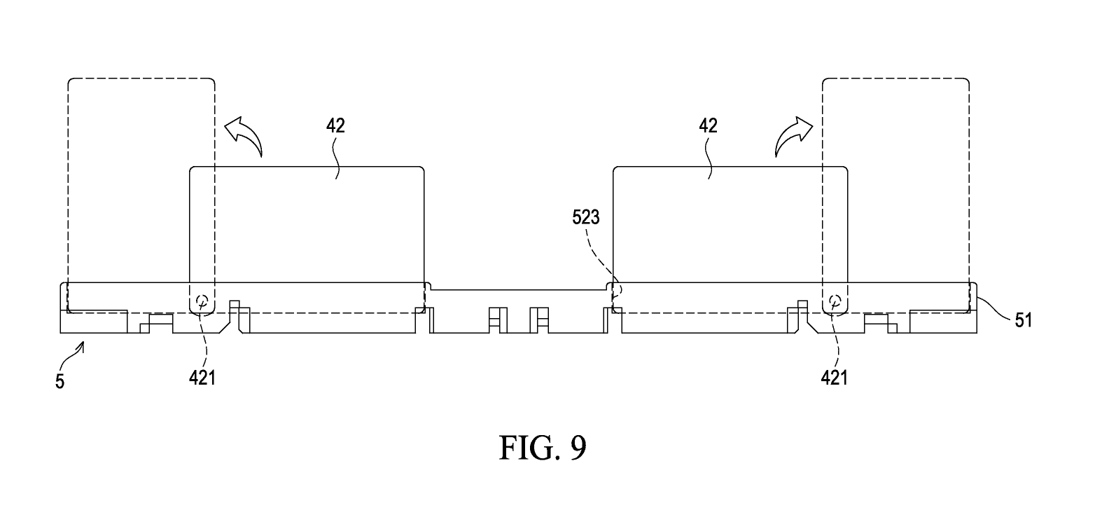

Referring to FIG. 9, a communication rack constructed in accordance with a third embodiment of the present invention is shown, the communication rack of the third embodiment is similar to that of the first embodiment, but comprises support plates 42 that are different from the support plates of the first embodiment and insertion slots 523 that have different size and number from the insertion slots of the first embodiment.

As shown, each of the insertion slots 523 and the support plate 42 that is inserted into the insertion slot 523 are provided with a pivot 421 therebetween. The pivot 421 pivotally connects the insertion slot 523 and a corner portion of the support plate 42, whereby the support plate 42 is allowed to rotate about the pivot 421 to convert the support plate 42 between a first condition where a long edge of the support plate 42 is inserted into the insertion slot 523 and a second condition where a short edge of the support plate is inserted into the insertion slot 523, so that the height of communication rack can be changed as desired.

### Fourth Embodiment

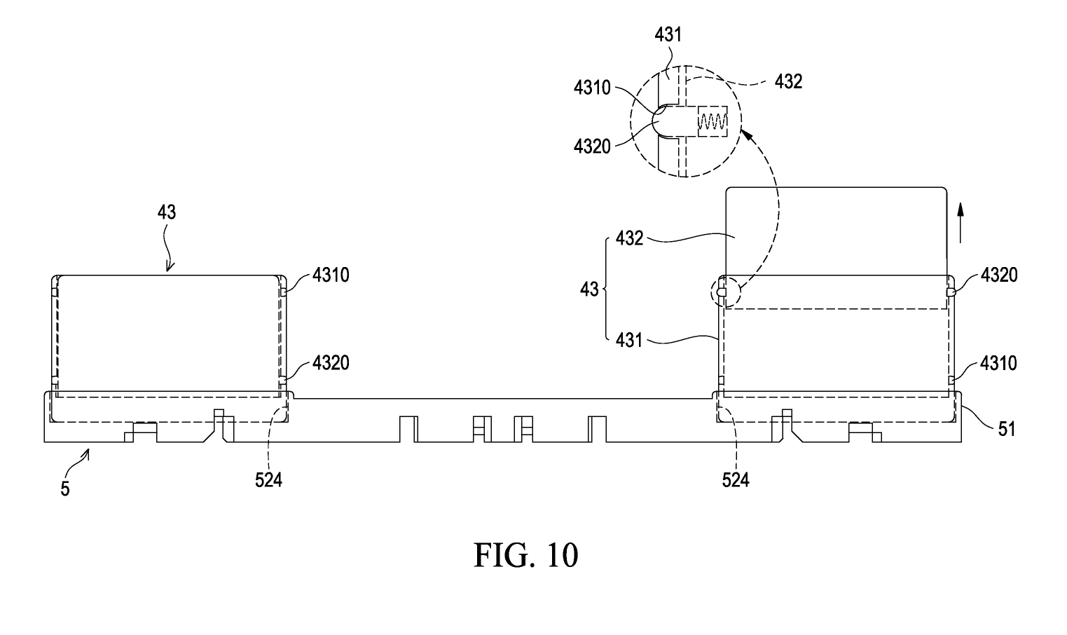

Referring to FIG. 10, a communication rack constructed in accordance with a fourth embodiment of the present invention is shown, the communication rack of the fourth embodiment is similar to that of the first embodiment, but comprises support plates 43 that are different from the support plates of the first embodiment and insertion slots 524 that have different size and number from the insertion slots of the first embodiment.

As shown, each of the support plate 43 comprises a base plate section 431 and an extension plate section 432 that is received in a compartment (not labeled) defined inside the base plate section 431 but is extendible out of the base plate section. Each extension plate section 432 has opposite side edges each having a lower end portion carrying a spring-based retractable member 4320, and the base plate section 431 forms a hole 4310 in an upper portion of each of two side walls that delimit the compartment to correspond in position to the spring-based member 4320. Lower portions of the side walls of the compartment of the base plate section 431 also form holes 4310 corresponding to the spring-based members 4320. (It is apparent that further holes 4310 can be formed in the side walls at any desired intermediate position between the upper and lower portions.) The spring-based members 4320 of the extension plate section 432 are resiliently extended into and thus engage the holes 4310 defined in either the upper portions or the lower portions of the side walls of the compartment of base plate section 431 to be respectively positioned at a raised position or lowered position with respect to the base plate section 431.

Thus, to raise to a desired height, the extension plate section 432 is pulled upward to allow the spring-based members 4320 of the extension plate section 432 to extend into the upper-portion holes 4310 to be positioned there; to lower to a desired height, the extension plate section 432 is depressed downward into the compartment of the base plate section 431 to allow the spring-based members 4320 of the extension plate section 432 to extend into the lower-portion holes 4310 to be positioned there. Preferably, each hole 4310 has an outer end opening that diverges in an outward direction to prevent the associated spring-based member 4320 from getting out of the hole. To change the height of the support plate 43, a slender or sharp object is used to depress the spring-based member 4320 inward to allow the extension plate section 432 to move upward or downward with respect to the base plate section.

### Fifth Embodiment

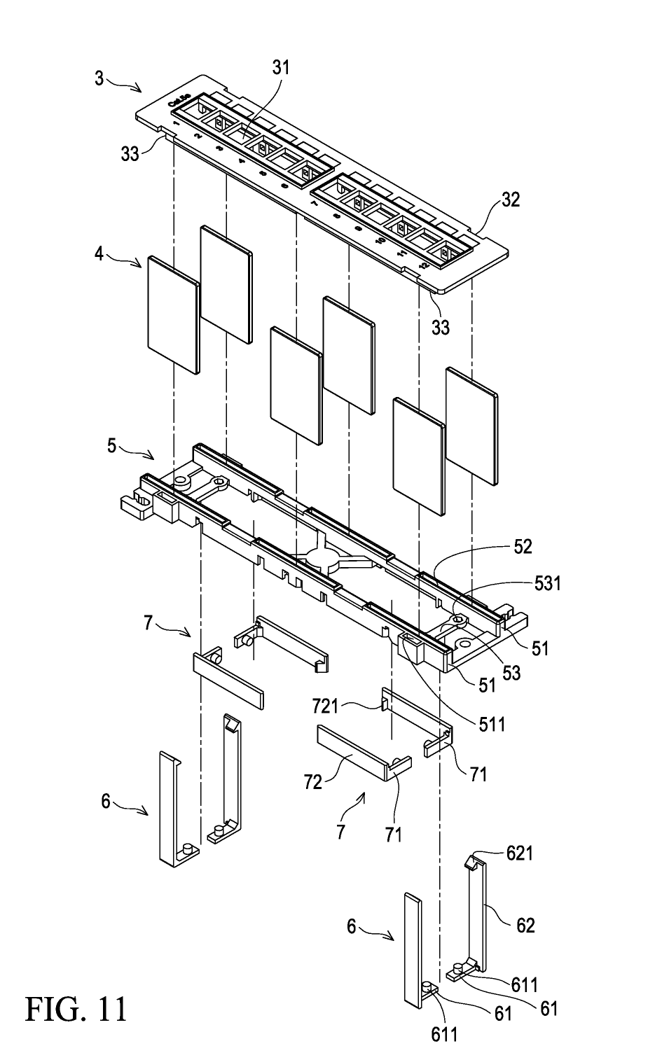

Referring to FIG. 11, a communication rack constructed in accordance with a fifth embodiment of the present invention is shown, the communication rack of the fifth embodiment is similar to that of the first embodiment, but comprises retainers (first retainer 6 and second retainer 7) that are made different from those of the first embodiment. The following description is made to the first retainer 6, and vice versa, also applicable to the second retainer 7. In the first embodiment described above, the first retainer 6 comprises two spring arms 62 that are connected to each other by a counterpart positioning section 61 connecting between ends of the spring arms 62, while in the fifth embodiment, the first retainer 6 comprises two spring arms 62 that are separate from each other and each of the separate spring arms 62 has an end forming a counterpart positioning section 61.

As shown, with the first retainer 6 being taken as an example for illustration, in the fifth embodiment, the counterpart positioning section 61 of each spring arm 62 forms a peg 611. Each spring arm 62 has an opposite end forming a pawl 621. Thus, each spring arm 62 uses the pawl 621 to engage a respective retention section 32 of the board 3 and uses the peg 611 to insert into and thus engage a respective hole 531 of the stand 5 for positioning.

The present invention provides a communication rack that has the following features. Since the height between the board 3 and the stand 5 can be easily adjusted, the communication rack can be used in a normal situation (of which the height is small), and can also be used in a condition where the amount of communication cables/wires is excessive (the height being made large). This is done by simply setting the support plates 4 horizontally or vertically, or alternatively selecting support plates 41 of desired height, or alternatively rotating the support plates 42 to horizontally oriented or vertically oriented, or alternatively depressing down or pulling upward an extension plate section 432 with respect to a base plate section of the support plates 43. The same stand can be applied to various situations without being disposed of. (The conventional rack may need a stand of a desired height and once the height does not meet, the stand must be replaced.) Thus, the present invention prevents any undesired waste. For those retainers (first retainer 6 and second retainer 7) that are not in use, they can be temporarily stored on the bottom of the stand 5 with the aid of the storage member 54 so that they will not get lost. With the interference induced between the spring arms 62 (72) and the reinforcement holes 511, the spring arms 62 (72) can be securely retained with respect to each other to enhance the engagement strength of the retainers (first retainer 6 and second retainer 7) with respect to the board 3. With the protrusions 552 provided inside the mounting slot 551 of the mounting sections 55, the projection provided on a wall can be securely constrained to securely and firmly mount the communication rack to the wall.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A communication rack, comprising:
a stand, which forms at least two insertion slot rows and a plurality of positioning sections arranged between the insertion slot rows, each of the insertion slot rows comprising at least one insertion slot;
at least one support plate, which is movably insert into the insertion slot of the stand;
a board, which comprises a plurality of retention sections, the board being positioned on and supported by the at least one support plate; and
a plurality of retainers, each of which comprises at least one counterpart positioning section and at least one pawl, the counterpart positioning section corresponding to the positioning section and fixed together, the pawl corresponding to and engaging with the retention sections.

2. The communication rack as claimed in claim 1, wherein the two insertion slot rows respectively comprise an insertion slot, and wherein the support plate comprises two side plate sections and a connection section connecting between ends of the two side plate sections, the two side plate sections being respectively and movably insert into the two insertion slots.

3. The communication rack as claimed in claim 1, wherein the two insertion slot rows respectively comprise a plurality of insertion slots, and wherein the at least one support plate comprises a plurality of support plates corresponding to the insertion slots, each of the support plates being movably insert into each of the insertion slots.

4. The communication rack as claimed in claim 3, wherein each of the insertion slots comprises a long shallow recess and a short deep recess that is made deeper than the shallow recess, each of the support plates having two long edges and two short edges, the long shallow recess being sized to receive movable insertion of one of the long edges of the respective support plate therein, the short deep recess being sized to receive movable insertion of one of the short edges of the respective support plate therein.

5. The communication rack as claimed in claim 3, wherein each of the insertion slots and the support plate inserted in the insertion slot comprise a pivot that pivotally connects a corner portion of the support plate to the insertion slot, the support plate having two long edges and two short edges, whereby the support plate is rotatable about the pivot with respect to the insertion slot to convert between a condition where one of the short edges is inserted into the insertion slot and a condition where one of the long edges is inserted into the insertion slot.

6. The communication rack as claimed in claim 3, wherein each of the support plate comprises a base plate section and an extension plate section that is received in the base plate section and is extendible out of the base plate section, the extension plate section having opposite edges each forming a retractable, spring-based member, the base plate section having opposite side walls each forming at least two holes corresponding to the spring-based member of the respective side edge of the extension plate section, whereby the spring-based member of each side edge of the extension plate section is allowed to be resiliently extended into one of the at least two holes of the respective side wall of the base plate section.

7. The communication rack as claimed in claim 1, wherein the retainers comprise a plurality of first retainer and a plurality of second retainer, the first retainer having a first length, the second retainer having a second length, the first length being different from the second length.

8. The communication rack as claimed in claim 7, wherein the stand has a bottom forming a plurality of storage members, the first retainer being arranged between the positioning sections and the retention sections, the second retainer being received and stored in the storage members.

9. The communication rack as claimed in claim 8, wherein each of the storage members comprises a base receiving channel for selectively receiving and positioning the counterpart positioning section of the first and second retainer, a first receiving channel for selectively receiving and positioning the pawl of the first retainer, and a second receiving channel for selectively receiving and positioning the pawl of the second retainer.

10. The communication rack as claimed in claim 1, wherein each of the retainers comprises two separate spring arms, each of which has an end forming the pawl and an opposite end forming the counterpart positioning section.

11. The communication rack as claimed in claim 1, wherein each of the retainers comprises two spring arms connected to each other, each of the spring arms having an end forming the pawl and an opposite end connected to each other by the counterpart positioning section.

12. The communication rack as claimed in claim 1, wherein each of the positioning sections of the stand forms a plurality of holes and wherein the counterpart positioning section of each of the retainers forms at least one peg corresponding to the holes, whereby the peg is selectively received in one of the holes.

13. The communication rack as claimed in claim 1, wherein the stand forms pairs of reinforcement holes through which each of the retainers is extendable to induce interference therebetween.

14. The communication rack as claimed in claim 1, wherein the stand comprises a plurality of mounting sections, each forming a mounting slot, which forms two opposing protrusions that are spaced from each other by a predetermined distance.
